(19) United States
(12) Patent Application Publication
(10) Pub. No.: US 2024/0106921 A1
(43) Pub. Date: Mar. 28, 2024

(54) PROTOCOL CONVERSION DEVICE, COMMUNICATION CABLE TEST METHOD, AND PROGRAM

(71) Applicant: Nippon Telegraph and Telephone Corporation, Tokyo (JP)

(72) Inventor: Kosuke WATANABE, Musashino-shi, Tokyo (JP)

(21) Appl. No.: 18/276,201

(22) PCT Filed: Feb. 9, 2021
(86) PCT No.: PCT/JP2021/004823

§ 371 Date: Aug. 7, 2023

(51) Int. Cl. H04L 69/08; G01R 31/58; H04L 12/66

(52) U.S. Cl. CPC H04L 69/08; G01R 31/58; H04L 12/66

(57) ABSTRACT

The quality of a communication cable can be efficiently determined. Therefore, a protocol conversion device includes a protocol converter for mutually converting between a message transfer part 2 message input/output from a public switched telephone network (PSTN) connector and an user peer-to-peer adaptation (M2PA) message input/output from an IP connector, a test signal output unit for outputting a test signal from the PSTN connector when a test instruction command is received, and a determination unit for outputting a determination result on the basis of whether or not the test signal has been received from the PSTN connector within a predetermined time from an output timing of the test signal.

### TECHNICAL FIELD

The present invention relates to a protocol conversion device, a communication cable test method, and a program.

### BACKGROUND ART

In recent years, a public switched telephone network (PSTN) of a common line signaling system has been replaced with an IP network which exchanges signal transmission messages in a SIGTRAN format. A protocol conversion device is inserted between a PSTN and an IP network for stepwise transition from the PSTN to the IP network. As an example thereof, Patent Literature 1 below describes a protocol conversion device for converting between an MTP2 message in PSTN layer 2 and an M2PA message in IP network layer 2. Further, a method of checking link control and conduction by a test signal in a PSTN is described in Non Patent Literature 1 below. The description of this literature is encompassed as parts of the present description.

### CITATION LIST

### Patent Literature

[PTL 1] Japanese Patent Application Laid-open No. 2019-9515

### Non Patent Literature

[NPL 1] TTC standard JT-Q703 “Message Transfer Part, Signaling Link,” Corporation of Telecommunication Technology Committee, 1994, “online,” “Retrieved 29 January, 2021,” Internet <URL: https://www.ttc.or.jp/application/files/2715/5427/9117/JT-Q703v3.pdf>

### SUMMARY OF INVENTION

### Technical Problem

However, when a communication failure has occurred between a device on the PSTN side (hereinafter referred to as a PSTN device) and a protocol conversion device, a failure of a communication cable connecting the PSTN device and the protocol conversion device may cause the failure. Therefore, it is desirable that the quality of the communication cable can be efficiently determined in order to search for the cause of the communication failure. However, Patent Literature 1 above does not specifically describe determination of the quality of a communication cable.

The present invention has been made in view of the above-described circumstances, and an object of the present invention is to provide a protocol conversion device, a communication cable test method, and a program capable of efficiently determining the quality of a communication cable.

### Solution to Problem

In order to solve the above problem, a protocol conversion device of the present invention includes a protocol converter including a PSTN connector connected to a PSTN device using a common signal line system, and an IP connector connected to an IP network, and configured to mutually convert between an MTP2 message input/output from the PSTN connector and an M2PA message input/output from the IP connector, a test signal output unit configured to output a test signal from the PSTN connector when a test instruction command is received, and a determination unit configured to output a determination result on the basis of whether or not the test signal has been received from the PSTN connector within a predetermined time from an output timing of the test signal.

### Advantageous Effects of Invention

According to the present invention, the quality of a communication cable can be efficiently determined.

### BRIEF DESCRIPTION OF DRAWINGS

FIG. 1 is a block diagram of a communication system according to a suitable embodiment.

FIG. 2 is a diagram showing layer configurations of a PSTN and an IP network.

FIG. 3 is a schematic diagram of a communication cable and a loopback connector.

FIG. 4 is a functional block diagram of a protocol conversion device.

FIG. 5 is a flowchart of a test processing program executed in a controller.

FIG. 6 is a diagram showing an example of a protocol conversion work procedure.

FIG. 7 is a diagram showing an example of a communication cable test method.

FIG. 8 is a diagram showing an example of a work procedure according to a first comparative example.

FIG. 9 is a diagram showing an example of a work procedure according to a second comparative example.

### DESCRIPTION OF EMBODIMENTS

### Configuration of Embodiment

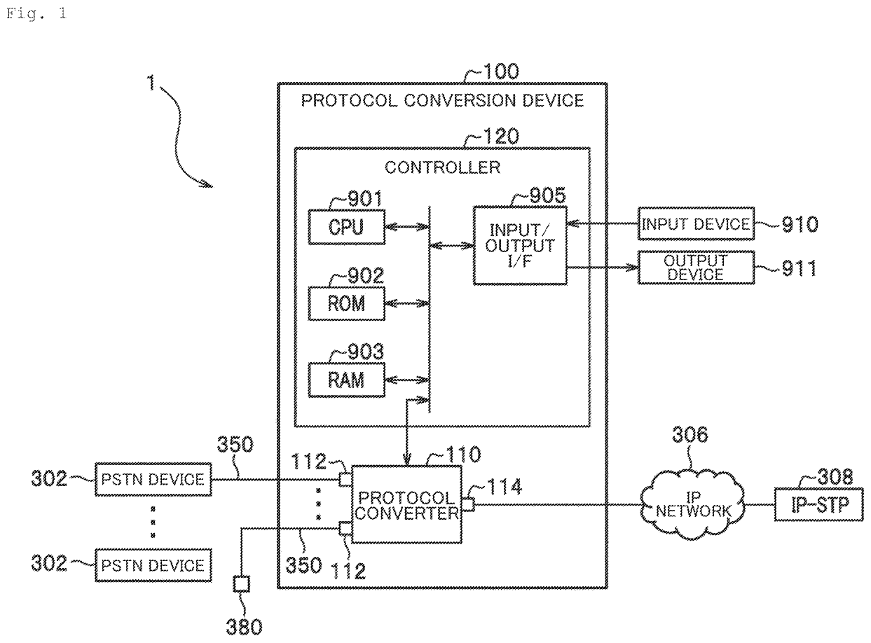

FIG. 1 is a block diagram of a communication system 1 according to a suitable embodiment.

In FIG. 1, the communication system 1 includes one or a plurality of PSTN devices 302, a protocol conversion device 100, an IP network 306, and an IP-STP device 308. The PSTN device 302 is a device in a PSTN of a common line signaling system. The common line signaling system is, for example, common channel signaling system No. 7 (SS7).

In operation, each PSTN device 302 is connected to the protocol conversion device 100 via a separate communication cable 350. However, in the illustrated state, some communication cables 350 are not connected to the PSTN device 302 and are connected to the loopback connector 380. This indicates that the communication cables 350 are under test. Details of test of the communication cables 350 will be described later.

The IP-STP device 308 is a signaling transfer point (STP) in the IP network 306. The IP network 306 is, for example, a network for exchanging signal transmission messages in a SIGTRAN format. The protocol conversion device 100 is connected to the IP-STP device 308 via the IP network 306.

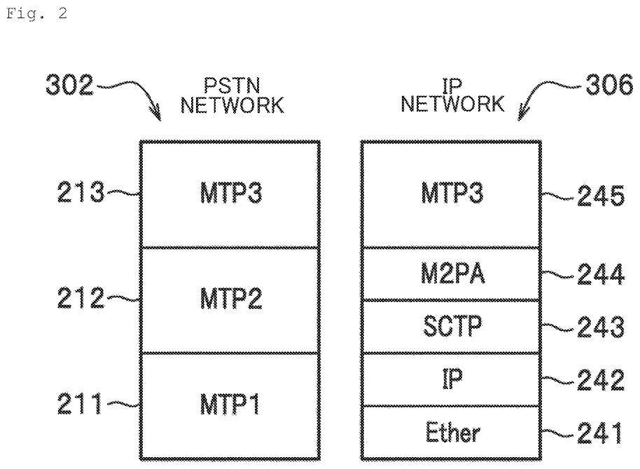

FIG. 2 is a diagram showing a layer configuration of the PSTN device 302 and the IP network 306. Layers in the PSTN, that is, the common line signaling system, include a message transfer part 1 (MTP1) layer 211 which is a signal data link part, a message transfer part 2 (MTP2) layer 212 which is a signal link function part, and a message transfer part 3 (MTP3) layer 213 which is a signal network function part. Meanwhile, layers in the IP network 306 include an Ether layer 241, an IP layer 242, a stream control transmission protocol (SCTP) layer 243, a user peer-to-peer adaptation (M2PA) layer 244, and an MTP3 layer 245.

The Ether layer 241 and the IP layer 242 in the IP network 306 correspond to the MTP1 layer 211 in the PSTN device 302. The SCTP layer 243 and the M2PA layer 244 in the IP network 306 correspond to the MTP2 layer 212 in the PSTN device 302. The MTP3 layer 245 in the IP network 306 and the MTP3 layer 213 in the PSTN device 302 have the same specifications.

Referring back to FIG. 1, the protocol conversion device 100 includes a protocol converter 110 and a controller 120 (computer). The protocol converter 110 is a device that performs protocol conversion between the MTP2 layer 212 in the PSTN device 302 (refer to FIG. 2) and the M2PA layer 244 in the IP network 306. As the protocol converter 110, the one described in Patent Literature 1 above can be applied.

The protocol converter 110 includes one or a plurality of PSTN connectors 112 and one IP connector 114. The PSTN connector 112 is a connector for inputting and outputting signals of the common line signaling system, and each communication cable 350 is connected to the PSTN connector 112. When the plurality of PSTN connectors 112 are provided as shown in the figure, an MTP1 interface may be distributed through a distribution device (not shown) and connected to the plurality of PSTN devices 302. Further, the IP connector 114 is, for example, a connector for inputting and outputting a signal in the SIGTRAN format and is connected to the IP network 306.

The controller 120 includes hardware as a computer, such as a central processing unit (CPU) 901, a read only memory (ROM) 902, a RAM 903, and an input/output interface (I/F) 905. The CPU 901 operates on the basis of a program stored in the ROM 902 and controls the protocol converter 110. Further, the CPU 901 controls an input device 910 such as a keyboard and an output device 911 such as a display via the input/output I/F 905. Accordingly, the CPU 901 acquires various types of data from the input device 910 and outputs generated data to the output device 911 via the input/output I/F 905. A graphics processing unit (GPU) or the like may be used along with the CPU 901 as a processor.

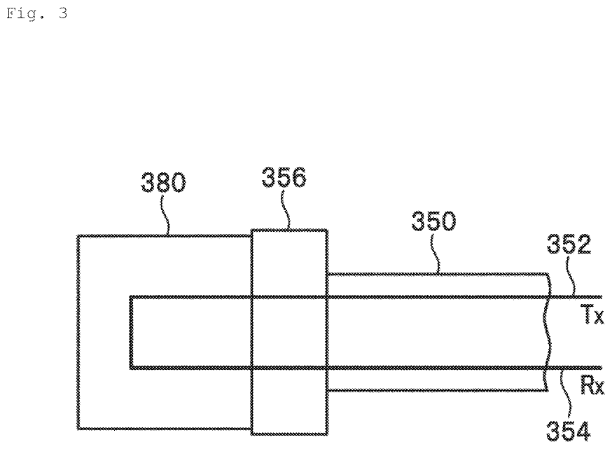

FIG. 3 is a schematic diagram of the communication cable 350 and the loopback connector 380.

The communication cable 350 includes a transmission line 352 and a reception line 354, and a connector 356 for connection is attached to an end portion of the communication cable 350. In addition, the loopback connector 380 is fitted to the connector 356 for connection as necessary. In the loopback connector 380, the transmission line 352 and the reception line 354 described above are connected.

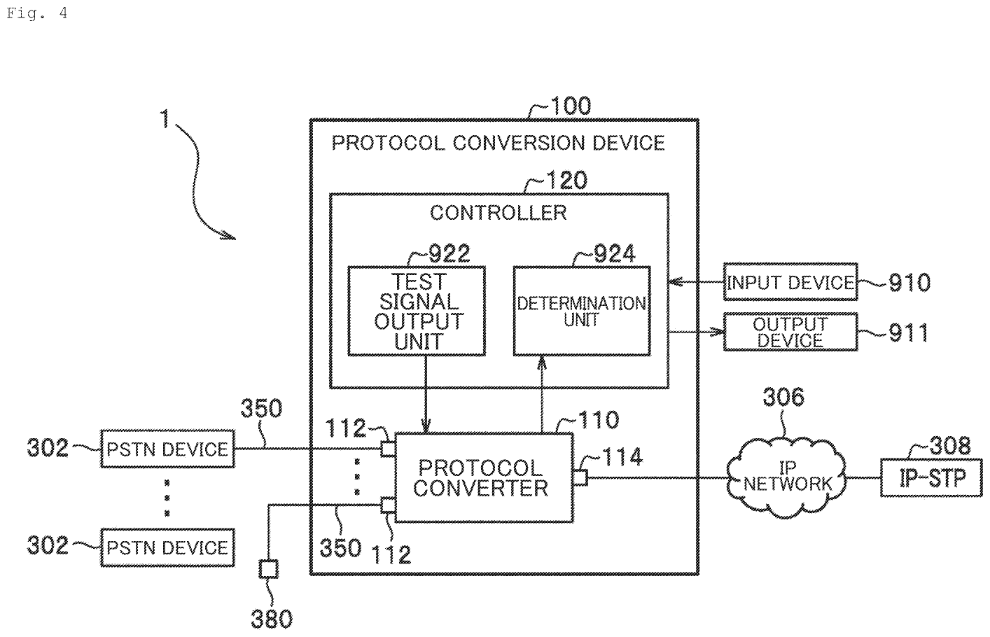

FIG. 4 is a functional block diagram of the protocol conversion device 100.

As described above, the protocol conversion device 100 includes the protocol converter 110 and the controller 120. In FIG. 4, functions realized by the CPU 901, the ROM 902, the RAM 903, the input/output I/F 905, and the like shown in FIG. 1 are shown inside the controller 120 as blocks.

That is, the controller 120 includes a test signal output unit 922 (test signal output means) and a determination unit 924 (determination means). The test signal output unit 922 receives, for example, a test instruction command from the input device 910. This test instruction command designates one or a plurality of arbitrary PSTN connectors 112 and commands output of a test signal. Here, the “test signal” is flag bits (“01111110”) conforming to the technical standard of MTP2.

However, in a case where the protocol converter 110 includes one PSTN connector 112 or all PSTN connectors 112 are test targets, the test instruction command may not include designation of a PSTN connector 112. The test signal output unit 922 outputs the test signal from one or a plurality of arbitrary PSTN connectors 112 which have been designated.

However, if the test instruction command does not include designation of a PSTN connector 112, the test signal output unit 922 transmits test signals from all PSTN connectors 112. The determination unit 924 determines whether or not each PSTN connector 112 that has output the test signal has received the test signal within a predetermined time and outputs a determination result to the output device 911.

### Operations of Embodiment

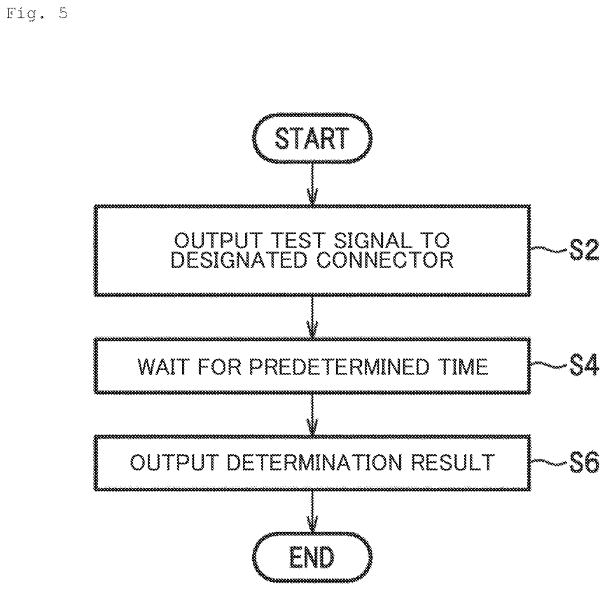

Next, operation of the present embodiment will be described. FIG. 5 is a flowchart of a test processing program executed in the controller 120

This program is started when the test signal output unit 922 receives a test instruction command. When the processing proceeds to step S2 in FIG. 5, the test signal output unit 922 transmits a test signal from a PSTN connector 112 designated by the test instruction command. Next, when processing proceeds to step S4, the determination unit 924 causes the processing to wait for a predetermined time.

Next, when the processing proceeds to step S6, the determination unit 924 determines a transmission/reception state of each PSTN connector 112 and outputs a determination result to the output device 911. Here, the determination result output to the output device 911 is, for example, one of J1 to J3 below.
J1: The corresponding PSTN connector 112 does not originally transmit a test signal.
J2: The corresponding PSTN connector 112 transmits a test signal and receives the test signal within a predetermined time.
J3: Although the corresponding PSTN connector 112 has transmitted the test signal, it has not received the test signal within the predetermined time period.

Accordingly, processing of this program ends.

It is assumed that the loopback connector 380 is connected to a certain PSTN connector 112 via the communication cable 350 (refer to FIG. 1). If the result of determination for the corresponding PSTN connector 112 is the aforementioned “J3”, there is a high likelihood that a failure such as disconnection has occurred in the communication cable 350. Therefore, according to the present embodiment, it is possible to efficiently determine the quality of the communication cable 350.

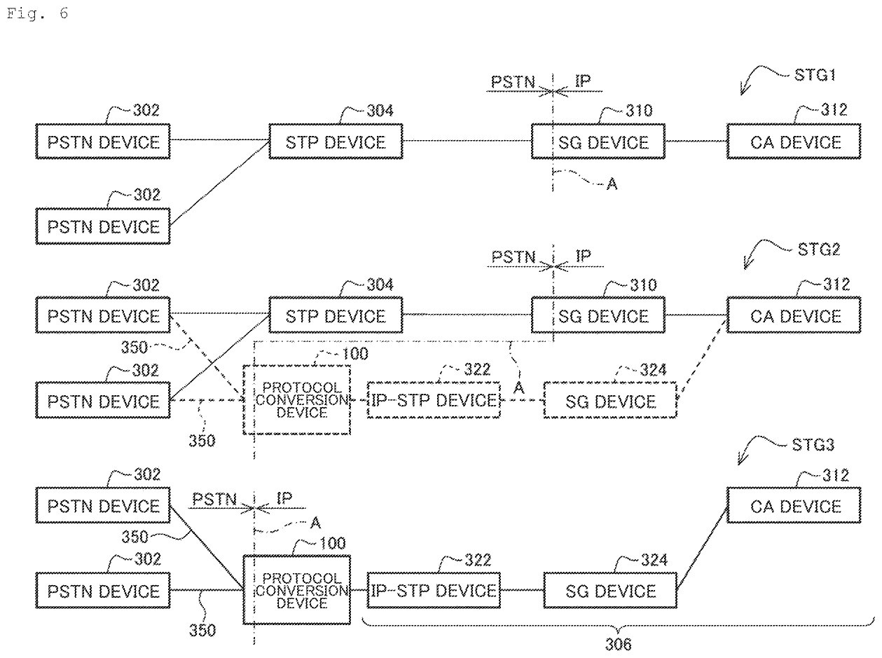

FIG. 6 is a diagram showing an example of a protocol conversion work procedure.

In FIG. 6, stages STG1, STG2, and STG3 show a state before a work, a state during the work, and a state after completion of the work. A dashed line A in the figure indicates the boundary of a communication system, and the right side of the dashed line A is an IP network, and the left side is a PSTN such as SS7.

In the stage STG1 shown in FIG. 6, a plurality of PSTN devices 302 are connected to an STP device 304 which is a signaling transfer point (STP) of the PSTN. The STP device 304 is connected to a signaling gateway (SG) device 310 which is a signaling gateway (SG), and the SG device 310 is connected to a call agent (CA) device 312 which is a CA. The SG device 310 performs protocol conversion between the IP network and the PSTN.

In the stage STG2 shown in FIG. 6, the protocol conversion device 100, an IP-STP device 322, and an SG device 324 indicated by a broken line are provided in addition to the above-mentioned configuration of the stage STG1. Communication cables 350 are laid between the plurality of PSTN devices 302 and the protocol conversion device 100. The elements indicated by broken line in the stage STG2 represent that a test is being performed.

When the test of the elements indicated by the broken line in the stage STG2 ends, the operation of these elements is started, and the STP device 304 and the SG device 310 are removed. This state is the stage STG3. The IP-STP device 322, the SG device 324, and the CA device 312 in the stage STG3 are parts of the IP network 306 shown in FIG. 1.

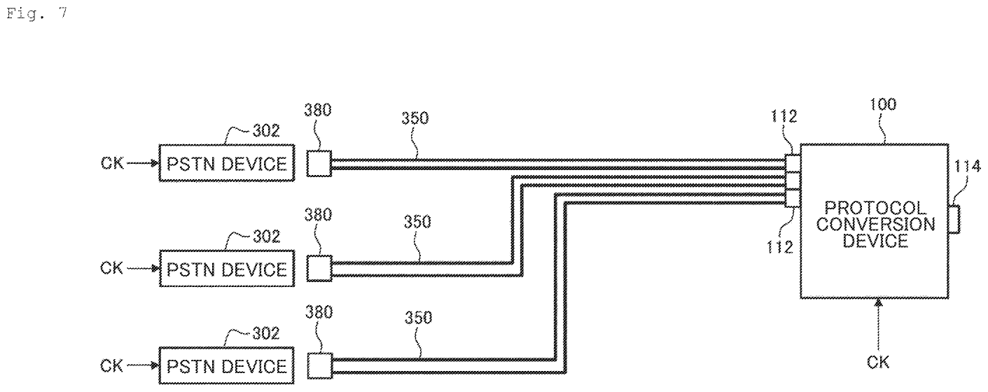

FIG. 7 is a diagram showing an example of a method of testing communication cables 350. The test is executed in the above-described stage STG2.

In FIG. 7, communication cables 350 are laid between a plurality of PSTN devices 302 and the protocol conversion device 100, and each one end of each communication cables 350 is connected to a corresponding PSTN connector 112. In the illustrated example, a loopback connector 380 is connected to the other end of each communication cable 350.

In this state, when an operator inputs a test instruction command for testing some or all of the PSTN connectors 112 through the input device 910 (refer to FIG. 1), test signals are output from the PSTN connectors 112 that are test targets. As described above, if a communication cable 350 is normal, the output test signal is returned to each PSTN connector 112 by the loopback connector 380. On the other hand, if there is a failure such as disconnection in a communication cable 350, the test signal is not returned from the communication cable 350. Accordingly, the above-described determination results J1 to J3 are displayed on the output device 911 (refer to FIG. 1), and the operator can recognize the quality of each communication cable 350.

When it is confirmed that the communication cable 350 is normal, the PSTN device 302 is connected to the PSTN connector 112 of the protocol conversion device 100 via the communication cable 350. Then, a synchronizing clock signal CK is supplied to each PSTN device 302 and the protocol conversion device 100, and the normality of communication therebetween is checked. In this stage, because the clock signal CK is not synchronized, or the like, for example, a communication failure may occur between the PSTN device 302 and the protocol conversion device 100. In the present embodiment, the normality of the communication cable 350 is checked in the stage before the PSTN device 302 and the protocol conversion device 100 are connected by the communication cable 350. Therefore, it is possible to eliminate the likelihood that the communication cable 350 is defective in investigating the cause of the failure, and it is possible to rapidly investigate the cause of the failure.

### First Comparative Example

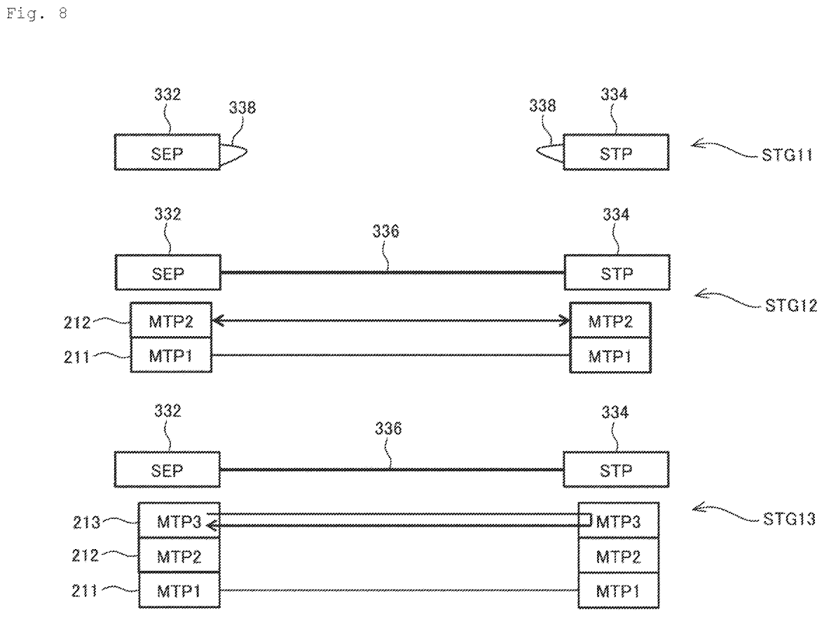

Hereinafter, various comparative examples will be described in order to clarify the effects of the present embodiment. First, FIG. 8 is a diagram showing an example of a work procedure according to a first comparative example. In the first comparative example, a signal end point (SEP) device 332 which is an SEP according to the common line signaling system and the signaling transfer point (STP) device 334 which is an STP are connected, and protocol conversion is not performed in particular.

In a stage STG11 shown in FIG. 8, loopback connectors 338 are respectively connected to the SEP device 332 and the STP device 334. Accordingly, both independently execute transmission/reception of a status indication “out of service” (SIOS) of the MTP2 layer 212, and independent normality is checked.

Next, in a stage STG 12, the SEP device 332 and the STP device 334 are connected by a communication cable 336. Accordingly, an MTP2 link is established therebetween, and the state of the MTP2 link is checked. Next, in a stage STG 13, the SEP device 332 and the STP device 334 transmit/receive a network management signal of the MTP3 layer 213 through mutual communication. Accordingly, it is confirmed that a route of the common line signaling system is established in the MTP3 layer 213.

### Second Comparative Example

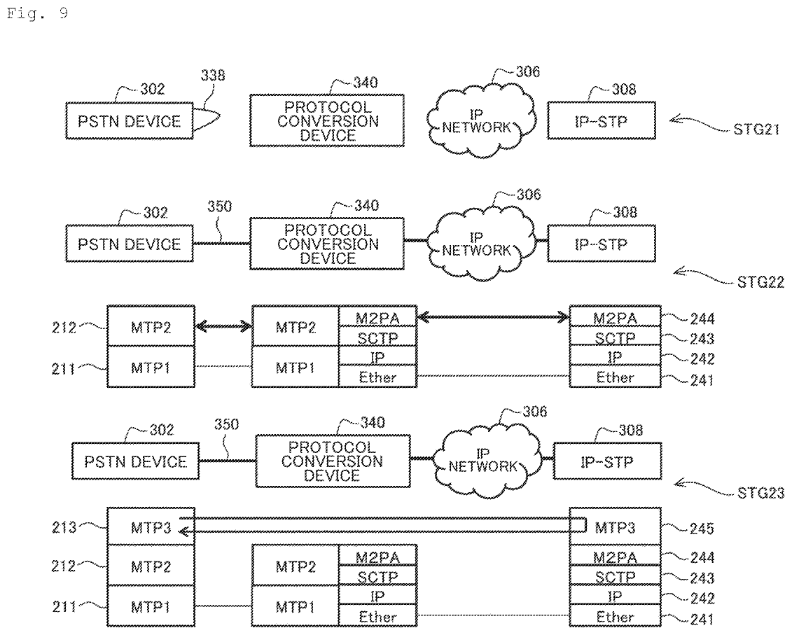

FIG. 9 is a diagram showing an example of a work procedure according to a second comparative example.

In the second comparative example, communication between a PSTN device 302 and an IP-STP device 308 is realized via a protocol conversion device 340 and an IP network 306. Here, the PSTN device 302, the IP network 306, and the IP-STP device 308 are the same as those of the above-described embodiment (refer to FIG. 1).

The protocol conversion device 340 in the second comparative example has a hardware configuration similar to that of the protocol conversion device 100 of the above-described embodiment (refer to FIG. 1). However, the protocol conversion device 340 is different from the protocol conversion device 100 of the above-described embodiment in that it does not have the test signal output unit 922 and the determination unit 924 (refer to FIG. 4).

In a stage STG21 of FIG. 9, the PSTN device 302, the protocol conversion device 340, the IP network 306, and the IP-STP device 308 are not connected to each other yet. Further, a loopback connector 338 is connected to the PSTN device 302. Accordingly, the PSTN device 302 independently performs transmission/reception of the status indication “out of service” (SIOS) of the MTP2 layer 212 as in the stage STG11 of the first comparative example, thereby independently checking normality.

Next, in a stage STG22, the PSTN device 302 and the protocol conversion device 340 are connected via a communication cable 350. Further, the protocol conversion device 340 is connected to the IP-STP device 308 via the IP network 306. Accordingly, a link of the MTP2 layer 212 and the M2PA layer 244 is established between the PSTN device 302 and the IP-STP device 308, and the state of the link is checked.

Next, in a stage STG23, a network management signal is transmitted/received between the PSTN device 302 and the IP-STP device 308 through the MTP3 layers 213 and 245 using mutual communication. Accordingly, it is confirmed that a route is established in the MTP3 layers 213 and 245.

In the second comparative example, a stage in which the normality of communication between the PSTN device 302 and the IP-STP device 308 can be checked is the stage STG22 and the following stages. However, even in the previous stage, if the protocol conversion device 340 and the IP-STP device 308 are connected to the IP network 306, for example, it is possible to check the normality of communication therebetween by transmitting and receiving a ping signal.

However, there has been no method of checking the normality of communication between the protocol conversion device 340 and the PSTN device 302 on the side of the protocol conversion device 340 in a stage prior to the stage STG22. This is because the protocol conversion device 340 does not have a function of supplying a signal of the MTP2 layer 212 to the PSTN device 302 unless the signal of the M2PA layer 244 is supplied from the IP network 306. Therefore, when a communication failure occurs in the stage STG22, it is necessary to investigate the cause of the failure including the likelihood of “failure of the communication cable 350,” and the work of investigating the cause of the failure becomes very complicated.

### Modified Examples

The present invention is not limited to the above embodiments and can be modified in various manners. The above-described embodiments are exemplified for the sake of easy understanding of the present invention, and are not necessarily limited to those having all the described configurations. Further, other components may be added to the components of the above-described embodiments, and some components may be replaced with other components Further, control lines and information lines shown in the drawings indicate those which are considered to be necessary for explanation, and do not necessarily indicate all the control lines and information lines necessary for products. In practice, it may be considered that almost all components are connected to each other. The following modifications are possible with respect to the above-described embodiments.
(1) Since the hardware of the controller 120 of the protocol conversion device 100 in the above-described embodiment can be realized by a general computer, the flowchart shown in FIG. 5, other programs for executing the above-described various types of processing, and the like may be stored in a storage medium or distributed through a transmission line.
(2) Although processing shown in FIG. 5 and each processing described above have been described as software processing using a program in the above-described embodiment, some of all thereof may be replaced by hardware processing using an application specific integrated circuit (ASIC), a field programmable gate array (FPGA) or the like.

### <Effects>

(1) According to the suitable embodiment as described above, the protocol conversion device 100 includes the protocol converter 110 including the PSTN connector 112 connected to the PSTN device 302 using a common signal line system and the IP connector 114 connected to the IP network 306 and configured to mutually convert between an MTP2 message input/output from the PSTN connector 112 and an M2PA message input/output from the IP connector 114, the test signal output unit 922 configured to output a test signal from the PSTN connector 112 when a test instruction command is received, and the determination unit 924 configured to output a determination result on the basis of whether or not the test signal has been received from the PSTN connector 112 within a predetermined time from an output timing of the test signal.

Accordingly, even when the M2PA message is not received from the IP connector 114, a test signal can be output from the PSTN connector 112. Therefore, when the loopback connector 380 is connected to the PSTN connector 112 via the communication cable 350, a result of determination of the quality of the communication cable 350 can be easily acquired, and thus the quality of the communication cable 350 can be efficiently determined.
(2) In addition, it is more desirable that the test signal is flag bits of MTP2 having a bit string of “01111110.” Accordingly, the quality of the communication cable 350 can be determined by using the test signal compatible with a communication signal of MTP2.
(3) Further, it is more desirable that the protocol converter 110 include a plurality of PSTN connectors 112, and the test instruction command includes information for designating a PSTN connector which will output the test signal among the plurality of PSTN connectors 112. Accordingly, the quality of a desired communication cable 350 among the communication cables 350 connected to the plurality of PSTN connectors 112 can be selectively determined.
(4) Further, according to another aspect, a suitable embodiment is a method of testing the communication cable 350 for executing a process of connecting one end of the communication cable 350 to the PSTN connector 112 of the protocol converter 110 including the PSTN connector 112 connected to the PSTN device 302 using a common signal line system and the IP connector 114 connected to the IP network 306 and configured to mutually convert between an MTP2 message input/output from the PSTN connector 112 and an M2PA message input/output from the IP connector 114, a process of connecting a loopback connector 380 to the other end of the communication cable 350, a process (S2) of outputting a test signal from the PSTN connector 112, and a process (S6) of outputting a determination result on the basis of whether or not the test signal has been received from the PSTN connector 112 within a predetermined time from an output timing of the test signal. Accordingly, the quality of the communication cable 350 can be efficiently determined.
(5) Further, according to another aspect, a suitable embodiment is a program applied to the protocol conversion device 100 including the protocol converter 110 including the PSTN connector 112 connected to the PSTN device 302 using a common signal line system and the IP connector 114 connected to the IP network 306 and configured to mutually convert between an MTP2 message input/output from the PSTN connector 112 and an M2PA message input/output from the IP connector 114, and a computer (120), the program causing the computer (120) to serve as a test signal output means (922) configured to output a test signal from the PSTN connector 112 when a test instruction command is received, and the determination means (924) configured to output a determination result on the basis of whether or not the test signal has been received from the PSTN connector 112 within a predetermined time from an output timing of the test signal. Accordingly, the computer (120) can be used to efficiently determine the quality of the communication cable 350.

### REFERENCE SIGNS LIST

100 Protocol conversion device
110 Protocol converter
112 PSTN connector
114 IP connector
120 Controller (computer)
302 PSTN device
306 IP network
350 Communication cable
380 Loopback connector
922 Test signal output unit (test signal output means)
924 Determination unit (determination means)

1. A protocol conversion device comprising:
a protocol converter including (i) public switched telephone network (PSTN) connector connected to a PSTN device using a common signal line system and (ii) an IP connector connected to an IP network, and configured to mutually convert between a message transfer part 2 (MTP2) message input/output from the PSTN connector and a user peer-to-peer adaptation (M2PA) message input/output from the IP connector;
a test signal output unit, implemented using one or more computing devices, configured to, based on a test instruction command being received, output a test signal from the PSTN connector; and
a determination unit implemented using one or more computing devices, configured to output a determination result based on whether the test signal has been received from the PSTN connector within a predetermined time from an output timing of the test signal.

2. The protocol conversion device according to claim 1, wherein the test signal is flag bits of MTP2 having a bit string of “01111110.”

3. The protocol conversion device according to claim 2, wherein the protocol converter includes a plurality of PSTN connectors, and the test instruction command includes information for designating a PSTN connector which will output the test signal among the plurality of PSTN connectors.

4. A communication cable test method comprising:
connecting a first end of a communication cable to a public switched telephone network (PSTN) connector of a protocol converter including (i) the PSTN connector connected to a PSTN device using a common signal line system and (ii) an IP connector connected to an IP network, and configured to mutually convert between a message transfer part 2 (MTP2) message input/output from the PSTN connector and a user peer-to-peer adaptation M2PA message input/output from the IP connector;
connecting a loopback connector to a second end of the communication cable;
outputting a test signal from the PSTN connector; and
outputting a determination result based on whether the test signal has been received from the PSTN connector within a predetermined time from an output timing of the test signal.

5. A non-transitory recording medium storing a program, wherein execution of the program causes a protocol conversion device comprising a computer and a protocol converter including (i) public switched telephone network (PSTN) connector connected to a PSTN device using a common signal line system and (ii) an IP connector connected to an IP network, and configured to mutually convert between a message transfer part 2 MTP2 message input/output from the PSTN connector and a user peer-to-peer adaptation M2PA message input/output from the IP connector, the program causing the computer to perform operations comprising:
outputting a test signal from the PSTN connector based on a test instruction command being received; and
outputting a determination result based on whether the test signal has been received from the PSTN connector within a predetermined time from an output timing of the test signal.
